(19) United States
(12) Patent Application Publication
(10) Pub. No.: US 2020/0373410 A1
(43) Pub. Date: Nov. 26, 2020

(54) CONTACT STRUCTURES OVER AN ACTIVE REGION OF A SEMICONDUCTOR DEVICE

(71) Applicant: GLOBALFOUNDRIES INC., Grand Cayman (KY)

(72) Inventors: TUNG-HSING LEE, Clifton Park, NY (US); SIPENG GU, Clifton Park, NY (US); JIEHUI SHU, Clifton Park, NY (US); HAITING WANG, Clifton Park, NY (US); ALI RAZAVIEH, Saratoga Springs, NY (US); WENJUN LI, Saratoga Springs, NY (US); KAVYA SREE DUGGIMPUDI, Clifton Park, NY (US); TAMILMANI ETHIRAJAN, Guilderland, NY (US); BRADLEY MORGENFELD, Greenfield Center, NY (US); DAVID NOEL POWER, Saratoga Springs, NY (US)

(21) Appl. No.: 16/423,035

(22) Filed: May 26, 2019

(51) Int. Cl. H01L 29/66; H01L 27/088; H01L 29/423; H01L 29/45; H01L 21/311; H01L 21/285; H01L 21/8234

(52) U.S. Cl. CPC H01L 29/66515; H01L 27/0886; H01L 29/42376; H01L 29/45; H01L 21/823475; H01L 21/28568; H01L 21/823431; H01L 21/823456; H01L 21/31116

(57) ABSTRACT

A method of fabricating a semiconductor device is provided, which includes providing a plurality of fins over a substrate and forming a plurality of first gate structures having a first gate pitch and a plurality of second gate structures having a second gate pitch traversing across a first and a second set of fins, respectively. The second gate pitch is wider than the first gate pitch. Epitaxial regions are formed between adjacent second gate structures in the second set of fins. A dielectric layer is deposited over the second gate structures and the epitaxial regions. Contact openings are formed in the dielectric layer. At least one of the contact openings is formed over the second gate structure where the second gate structure traverses across the second set of fins. The contact openings are filled with a conductive material to form contact structures electrically coupled to the second gate structures.

### FIELD OF THE INVENTION

The disclosed subject matter relates generally to methods of forming semiconductor devices and, more particularly, to methods of forming contact structures over an active region of a semiconductor device and the resulting semiconductor devices therefrom.

### BACKGROUND

Technological advances in the semiconductor integrated circuit (IC) industry have brought tremendous device miniaturization, along with performance improvements. Scaling is critical to obtain higher performance speed in IC devices, resulting in higher device density and smaller sized IC devices. Conventional IC processing requires forming contacts to the various features of an IC device. There are several challenges in fabricating contacts for use with increasingly smaller features.

One of the challenges of fabricating IC contacts is ensuring that gate contacts are not electrically short-circuited to neighboring source/drain regions within an active region. As a result of technology scaling, gate structures are formed increasingly closer to each other, and the gate-to-gate spacing becomes so narrow that a minor misalignment for the gate contact may electrically short the gate contact to the neighboring source/drain region. As a result, conventional IC designs require the gate contacts to be placed over isolation regions, away from the active regions. Placing gate contacts over the isolation regions creates a longer gate transporting length and a higher gate resistance that may be undesirable for some IC devices whose performances are sensitive to gate resistance.

For the reasons described above, there is a need to devise methods of forming contact structures over an active region of a semiconductor device and the resulting semiconductor devices having such contact structures.

### SUMMARY

To achieve the foregoing and other aspects of the present disclosure, methods of forming contact structures over an active region of a semiconductor device and the resulting semiconductor devices are presented.

According to an aspect of the disclosure, a method of fabricating a semiconductor device is provided that includes providing a plurality of fins over a substrate and forming a plurality of first gate structures having a first gate pitch. The plurality of first gate structures traverse across a first set of fins. A plurality of second gate structures are formed having a second gate pitch traversing across a second set of fins. The second gate pitch is wider than the first gate pitch. A plurality of epitaxial regions are formed in spaces between adjacent second gate structures in each of the traversed second set of fins. A dielectric layer is deposited over the plurality of second gate structures and the plurality of epitaxial regions. A plurality of contact openings are formed in the dielectric layer and at least one of the contact openings is formed over the second gate structure at a location where the second gate structure traverses across the second set of fins. The plurality of contact openings are filled with a conductive material to form a plurality of contact structures electrically coupled to the second gate structures.

According to another aspect of the disclosure, a method of fabricating a semiconductor device is provided that includes providing a plurality of fins over a substrate and forming a plurality of first gate structures having a first gate pitch. The plurality of first gate structures traverse across a first set of fins. A plurality of second gate structures are formed having a second gate pitch traversing across a second set of fins. The second gate pitch is wider than the first gate pitch. A plurality of epitaxial regions are formed in spaces between adjacent second gate structures on each of the traversed second set of fins. A dielectric layer is deposited over the plurality of second gate structures and the plurality of epitaxial regions. A plurality of discrete contact openings are etched in the dielectric layer to form a plurality of first contact openings. Each of the first contact openings is formed over each of the second gate structures at a location where the second gate structure traverses across one of the second set of fins. The plurality of first contact openings are filled with a conductive material to form a plurality of first contact structures electrically connected to the second gate structures.

According to yet another aspect of the disclosure, a semiconductor device is provided that includes a substrate, a plurality of fins, a plurality of first gate structures, a plurality of second gate structures, a plurality of epitaxial regions, and a first contact structure. The plurality of first gate structures and the plurality of second gate structures traverse across the plurality of fins. The plurality of first gate structures have a first gate pitch and the plurality of second gate structures have a second gate pitch, with the second gate pitch being wider than the first gate pitch. A plurality of epitaxial regions are formed in each of the fins, wherein the epitaxial regions are interposed between adjacent second gate structures. A first contact structure is positioned over each of the second gate structures traversing across at least one of the plurality of fins. The first contact structure is electrically coupled to at least one of the plurality of second gate structure.

### BRIEF DESCRIPTION OF THE DRAWINGS

The embodiments of the present disclosure will be better understood from a reading of the following detailed description, taken in conjunction with the accompanying drawings:

FIG. 1 is a top view of a semiconductor device, according to an embodiment of the disclosure.

FIG. 2 is a top view of a semiconductor device, according to another embodiment of the disclosure.

FIGS. 3A-3I are enlarged cross-sectional views of a semiconductor device (taken along a line X-X′ as indicated in FIG. 1), depicting a method of forming contact structures over an active region of a semiconductor device, according to an embodiment of the disclosure.

FIGS. 4A-4H are enlarged cross-sectional views of a semiconductor device (taken along a line X-X′ as indicated in FIG. 2), depicting another method of forming contact structures over an active region of a semiconductor device, according to an embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the disclosure. Additionally, elements in the drawings are not necessarily drawn to scale. For example, the dimensions of some of the elements in the drawings may be exaggerated relative to other elements to help improve understanding of embodiments of the disclosure. The same reference numerals in different drawings denote the same elements, while similar reference numerals may, but do not necessarily, denote similar elements.

### DETAILED DESCRIPTION

Various embodiments of the disclosure are described below. The embodiments disclosed herein are exemplary and not intended to be exhaustive or limiting to the disclosure.

The present disclosure relates to methods of forming contact structures over an active region of a semiconductor device and the resulting semiconductor devices. It is understood that the following disclosure is not limited to any particular type of semiconductor devices. The method disclosed herein may be applied to any type of semiconductor devices, such as tri-gate field effect transistor (FET) devices, fin-type FET (FinFET) devices or planar-type metal-oxide-semiconductor FET (MOSFET) devices.

The semiconductor device may be fabricated with a gate-first, a gate-last or a hybrid fabrication process. In a gate-first process, conductive layers are formed over active regions and patterned to form gate structures. This is followed by conventional complementary metal-oxide-semiconductor (CMOS) processing, including formation of source and drain regions, formation of spacers and deposition of inter-level dielectric (ILD) material. In a gate-last process, dummy gate structures are formed followed by conventional CMOS processing including formation of the source and drain regions, formation of spacers and deposition of ILD material. Thereafter, the dummy gate structures are removed followed by conventional formation of replacement gate structures. In the hybrid fabrication process, a gate structure of one type of device may be formed first and a gate structure of another type of device may be formed last.

Aspects of the disclosure are now described in detail with accompanying drawings. It is noted that like and corresponding elements are referred to by the use of the same reference numerals. However, it is noted that specific elements may be denoted by a reference numeral and a subscript, for example 108a, 108b, etc. When those elements are referred to generically, merely the reference numerals are used, for example 108, 206, etc.

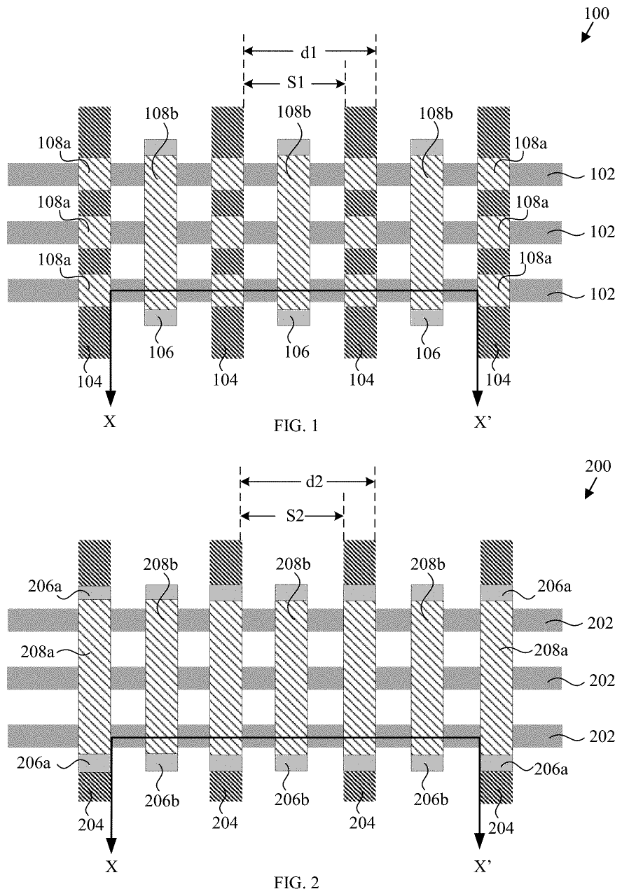

FIG. 1 is a simplified top view of a semiconductor device 100, according to an embodiment of the disclosure. The semiconductor device 100 includes an array of active regions 102, a plurality of gate structures 104, a plurality of interconnect structures 106 and a plurality of contact structures 108. The plurality of gate structures 104 and the plurality of interconnect structures 106 traverse across the array of active regions 102. A plurality of epitaxial regions (not shown) are formed in each of the active regions 102 between adjacent gate structures 104, and the plurality of interconnect structures 106 are formed over the plurality epitaxial regions, each of the interconnect structures 106 traversing across the array of active regions 102.

The contact structures 108a are formed over the gate structures 104 and the contact structures 108b are formed over the interconnect structures 106. The contact structures 108a provide electrical contact to the gate structures 104. The contact structures 108a may be in a form of a discrete contact structure, i.e., individual contact structures having a generally square-like or cylindrical shape that typically couple to one active region 102. The contact structures 108b are electrically coupled to the epitaxial regions through the interconnect structures 106. The contact structures 108b may be in a form of line-type contact structures that typically traverse across at least two active regions 102 of the semiconductor device 100.

FIG. 2 is a simplified top view of a semiconductor device 200, according to another embodiment of the disclosure. As in the semiconductor device of FIG. 1, the semiconductor device 200 includes an array of active regions 202, a plurality of gate structures 204, a plurality of interconnect structures 206 and a plurality of contact structures 208. The plurality of gate structures 204 traverse across the array of active regions 202. A plurality of epitaxial regions (not shown) are formed in each of the active regions 202 between adjacent gate structures 204.

The interconnect structures 206a are formed over the gates structures 204 and the interconnect structures 206b are formed over the epitaxial regions traversing across the array active regions 102. The contact structures 208 are formed over the interconnect structures 206. The interconnect structures 206a provide electrical contact between the gate structures 204 and the contact structures 208a, and the interconnect structures 206b provide electrical contact between the epitaxial regions and the contact structures 208b, respectively. The contact structures 208 may be all line-type contact structures that typically traverse across at least two active regions 202 of the semiconductor device 200, without the use of any discrete contact structures.

While the active regions (102 and 202, respectively) are represented as fins in the accompanying drawings, it is understood that the fin is used only as a non-limiting example of the active regions (102 and 202, respectively), and other active regions (e.g., a doped layer on a top surface of a bulk semiconductor substrate or a semiconductor-on-insulator layer) may be used as well. It should also be understood that the present disclosure can be applied to any type of transistor device architecture, such as a three-dimensional device architecture (e.g., FinFETs), or a planar device architecture (e.g., complementary metal oxide semiconductor (CMOS) devices), semiconductor-on-insulator (SOI) devices). In this embodiment of the present disclosure, the active regions 102 and 202 are preferably fins of FinFET semiconductor devices. Furthermore, those skilled in the art would recognize, after a complete reading of the disclosure, the number and placement locations of the active regions (102 and 202, respectively), the gate structures (104 and 204, respectively), the interconnect structures (106 and 206, respectively) and the contact structures (108 and 208, respectively) may vary according to the specific designs of the semiconductor devices.

As illustrated in FIG. 1, the plurality of gate structures 104 are separated by a gate pitch d1, with a corresponding gate-to-gate spacing S1 between adjacent gate structures 104. Also illustrated in FIG. 2, the plurality of gate structures 204 are separated by a gate pitch d2, with a corresponding gate-to-gate spacing S2 between adjacent gate structures 204.

The term “gate pitch” as used herein defines a distance from a left edge of a gate structure to a left edge of an adjacent identical gate structure. The minimum gate pitch in a semiconductor device is termed “contacted poly pitch” (CPP), with a corresponding minimum gate-to-gate spacing. The term “spacing” as used herein defines a distance between two adjacent structures.

In this embodiment of the disclosure, the gate pitch d1 of FIG. 1 and the gate pitch d2 of FIG. 2 are preferable to have a width wider than the CPP of the semiconductor devices (100 and 200, respectively). For example, the gate pitch d1 may have a width wider than 1.5×, 2×or 3× the CPP of the semiconductor device 100, i.e., 1.5×CPP, 2×CPP or 3×CPP, respectively. The gate pitch d1 of FIG. 1 may or may not have the same width as the gate pitch d2 of FIG. 2. It is understood that there are other gate structures formed on different portions of the semiconductor devices (100 and 200, respectively) having the minimum gate pitch of 1×CPP, although those gate structures are not shown in the accompanying drawings.

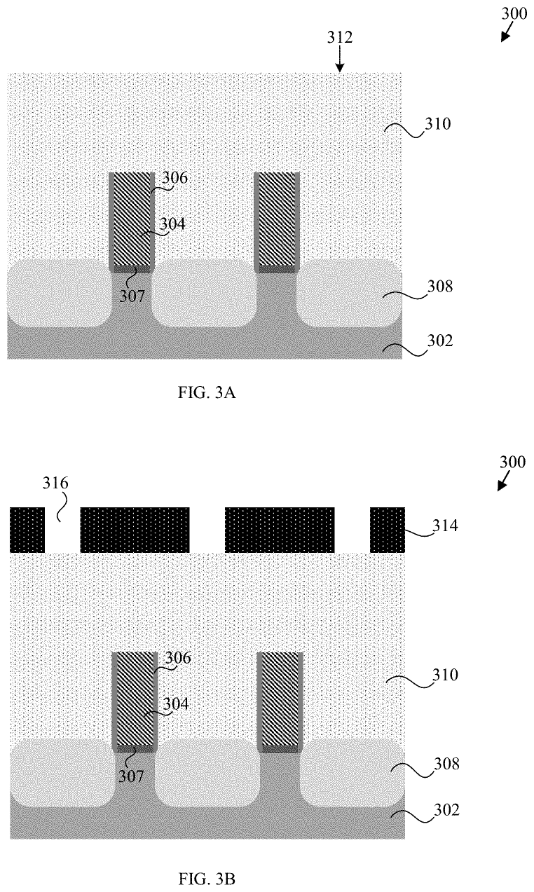

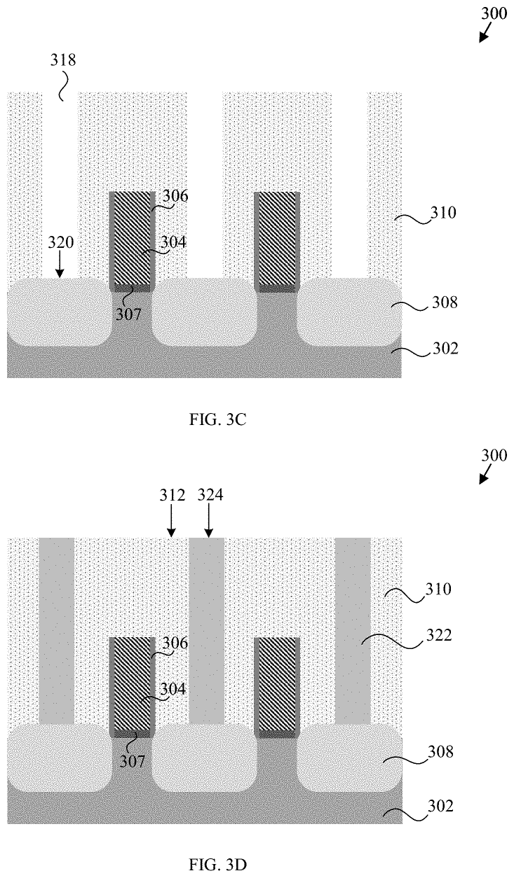

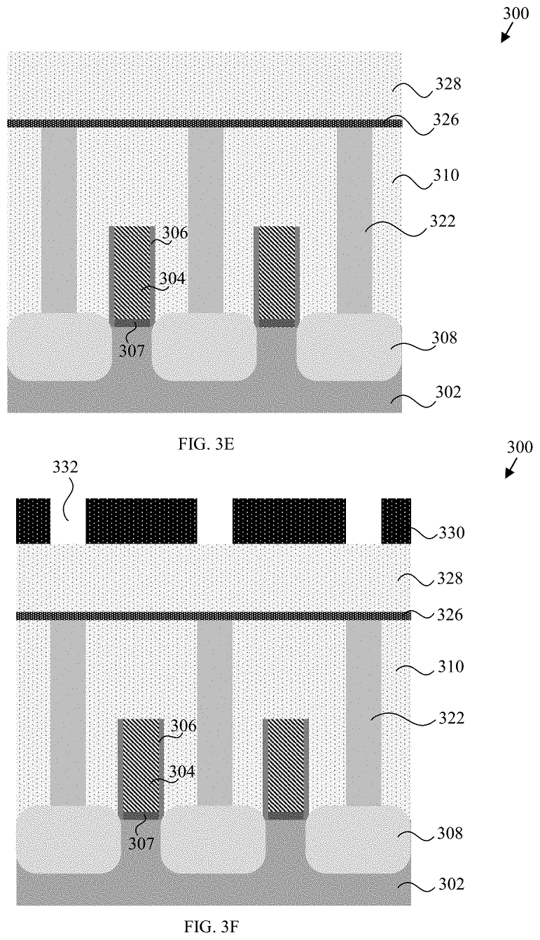

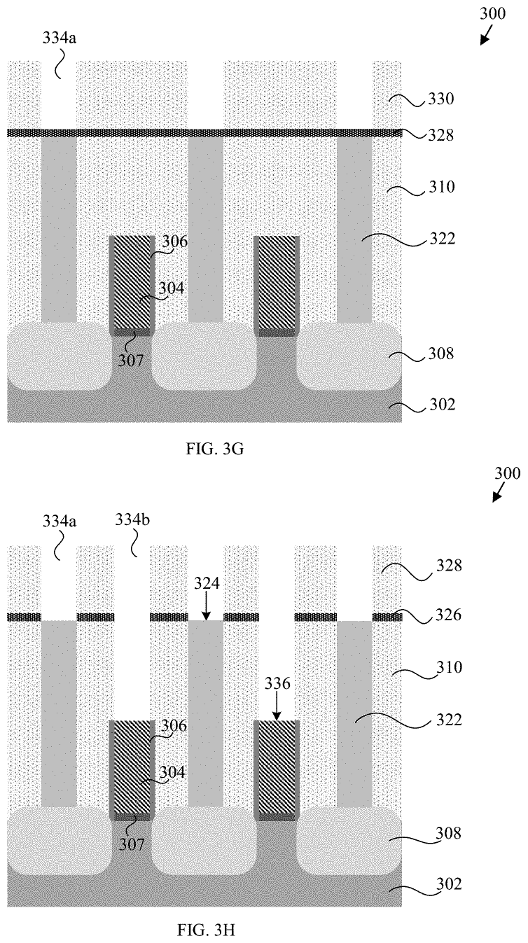

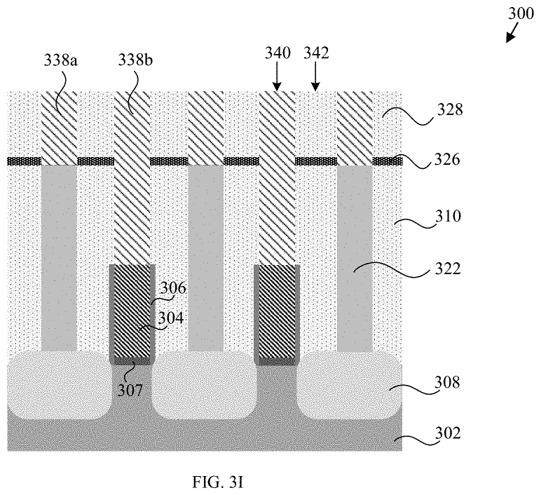

With continuing reference from FIG. 1 and, in particular, the line X-X′ shown therein, FIGS. 3A-3I are enlarged cross-sectional views of a semiconductor device 300 (taken along a similar line X-X′), illustrating a method of forming contact structures over an active region of the semiconductor device, according to an embodiment of the disclosure. It is understood that the specific arrangement of the semiconductor device 300 is used for illustration purposes only and that a variety of possible layouts may benefit from embodiments of the disclosure described herein.

FIG. 3A is a cross-sectional view of the semiconductor device 300 having an active region 302 and gate structures 304, according to an embodiment of the disclosure. The gate structures 304 are formed over the active region 302 and each of the gate structures 304 has sidewalls disposed with gate spacers 306 and a gate dielectric layer 307. The gate spacers 306 may be formed of a suitable low-k dielectric material, i.e., a dielectric material having a low dielectric constant, preferably silicon nitride, silicon oxide or any suitable low-k dielectric material to at least contribute to electrically isolate the gate structure 304 from adjacent conductive features. Each of the gate structures 304 is interposed between two epitaxial regions 308. The epitaxial regions 308 are typically formed by an epitaxial growth process and additional implantation process and form source/drain regions of the semiconductor device 300.

The gate structure 304 typically includes a layer of gate insulating material (e.g., a layer of high-k dielectric material having a dielectric constant of typically 10 or greater) or silicon dioxide, and one or more conductive material layers (e.g., metal and/or polysilicon), that serve as gate electrode for the gate structure 304. The gate insulating material and the conductive material layers are not separately shown in the accompanying drawings.

A dielectric layer 310 is deposited over the gate structures 304 and the epitaxial regions 308 using a suitable deposition process. The dielectric layer 310 may be deposited in a one or a multi-step process, and a suitable planarization process may be performed to form a substantially planar top dielectric surface 312. The dielectric layer 310 is preferably a dielectric material, e.g., silicon dioxide, suitable to electrically isolate conductive features ultimately formed therein while maintaining a robust structure during the subsequent processing steps.

FIG. 3B illustrates the semiconductor device 300 after depositing a patterning layer 314 and forming openings 316 in the patterning layer 314, according to an embodiment of the disclosure. The patterning layer 314 is deposited over the dielectric layer 310 and the openings 316 are formed in the patterning layer 314 using suitable deposition and lithographic processes. The openings 316 are aligned over the epitaxial regions 308 and expose portions of the dielectric layer 310. The patterning layer 314 may include a spin-on hard mask (SOH) layer, a photoresist layer, or any suitable patterning layer having any suitable thickness. The patterning layer 314 may also include a multi-layer stack of patterning materials.

FIG. 3C illustrates the semiconductor device 300 after forming interconnect openings 318 in the dielectric layer 310, according to an embodiment of the disclosure. The openings 316 in the patterning layer 314 are extended through the dielectric layer 310 using a suitable material removing process to form the interconnect openings 318 in the dielectric layer 310 over the epitaxial regions 308. Top surfaces 320 of the epitaxial regions 308 are exposed in the interconnect openings 318. In one embodiment of the disclosure, the interconnect openings 318 have a line-type opening that traverses across at least two active regions 302 of the semiconductor device 300. In another embodiment of the disclosure, the material removing process is a dry etching process.

FIG. 3D illustrates the semiconductor device 300 after forming interconnect structures 322, according to an embodiment of the disclosure. The interconnect structures 322 are formed in the dielectric layer 310 over the epitaxial regions 308 and may be formed by any suitable process, including an exemplary process described herein. A conductive material is deposited in the interconnect openings 318 using a suitable deposition process. The conductive material may overfill the interconnect openings 318 and a suitable planarization process may be performed to form a top interconnect surface 324 substantially coplanar with the top surface 312 of the dielectric layer 310.

The interconnect structures 322 are electrically connected to the epitaxial regions 308. The interconnect structures 322 may be in a form of line-type structures that traverse across at least two active regions 302 of the semiconductor device 300. The conductive material may include tungsten, copper, aluminum, alloys of these metals and/or combinations thereof. In one embodiment of the disclosure, the interconnect structures 322 are preferably formed of tungsten.

Although not shown in FIG. 3D, one or more liners may be deposited during the formation of the interconnect structures 322. For instance, an adhesion liner and/or a barrier liner may be deposited in an interconnect opening before a conductive material deposition. The adhesion liner may include metal silicides, such as titanium silicide, nickel silicide or other suitable adhesion material having any suitable thickness. The barrier liner may include metal nitrides, such as titanium nitride, tantalum nitride or other suitable barrier material having any suitable thickness.

FIG. 3E illustrates the semiconductor device 300 after depositing of an etch stop layer 326 and a dielectric layer 328, according to an embodiment of the disclosure. The etch stop layer 326 is deposited over the dielectric layer 310 and the interconnect structures 322, and the dielectric layer 328 is deposited over the etch stop layer 326, using suitable deposition processes. The dielectric layer 328 may or may not be the same dielectric material as the dielectric layer 310. In this embodiment of the disclosure, the dielectric layer 328 and the dielectric layer 310 are the same dielectric material. Also in another embodiment of the disclosure, the etch stop layer 326 is a contact etch stop layer (CESL), and may preferably include a material that exhibits high etch selectivity to the dielectric layer 328. For instance, an employed material removing process may remove the dielectric layer 320 without substantially removing the etch stop layer 326. The etch stop layer 326 may include a silicon carbonitride layer, a silicon nitride layer, a silicon carbide layer or other suitable etch stop layer having any suitable thickness.

FIG. 3F illustrates the semiconductor device 300 after depositing a patterning layer 330 and forming openings 332 in the patterning layer 330, according to an embodiment of the disclosure. The patterning layer 330 is deposited over the dielectric layer 328 and the openings 332 are formed in the patterning layer 330 using suitable deposition and lithographic processes. The openings 332 are aligned over the interconnect structures 332. The patterning layer 330 may include a spin-on hard mask (SOH) layer, a photoresist layer, or any suitable patterning layer having any suitable thickness. The patterning layer 330 may also include a multi-layer stack of patterning materials.

FIG. 3G illustrates the semiconductor device 300 after forming a first set of contact openings 334a in the dielectric layer 320, according to an embodiment of the disclosure. The openings 332 in the patterning layer 330 are extended through the dielectric layer 330 using a suitable material removing process to form the contact openings 334a. Due to the high etch selectivity between the etch stop layer 326 and the dielectric layer 330, the extension of the openings 332 through the etch stop layer 326 will be substantially impeded due to a lower material removal rate of the etch stop layer 326. The contact openings 334a expose portions of the etch stop layer 326. The contact openings 334a may be in a form of line-type openings that typically traverse across at least two active regions 302.

The material removing process may include one or more dry etching processes, wet etching processes, other suitable etching processes (e.g., reactive ion etching), and/or combinations thereof. The contact openings 334a preferably have the same width as the interconnect structures 314, even though wider or narrower widths have been contemplated.

FIG. 3H illustrates the semiconductor device 300 after forming a second set of contact openings 334b in the dielectric layer 328, according to an embodiment of the disclosure. The contact ope0nings 334b are formed in the dielectric layer 328 using suitable lithographic and material removing processes. The contact openings 334a have also been extended through the etch stop layer 326 during the same material removing process step, exposing the top surfaces 324 of the interconnect structures 332. The contact openings 334b are formed over the gate structures 304, exposing top surfaces 336 of the gate structures 304. The contact openings 334b preferably have the same width as the gate structures 304, even though wider or narrower widths have been contemplated. The contact openings 334b may be in a form of discrete contact openings having a square-like or cylindrical shape that typically confine to one active region 302.

FIG. 3I illustrates the semiconductor device 300 after forming contact structures 338, according to an embodiment of the disclosure. The contact structures 338 may be formed by an exemplary process described herein. A conductive material is deposited in the contact openings 334. The conductive material may overfill the contact openings 334 and a suitable planarization process may be performed to form top contact surfaces 340 substantially coplanar with a top surface 342 of the dielectric layer 328. The contact structures 338a are electrically connected to the epitaxial regions 308 through the interconnect structures 322 and the contact structures 338b are electrically connected to the gate structures 304, respectively.

As illustrated by the semiconductor device 100 shown in FIG. 1, the contact structures 338a may be in a form of discrete contact structure having a generally square-like or cylindrical shape that typically couple to one active region 302 and the contact structures 338b have a line-type structure that typically traverses across at least two active regions 302 of the semiconductor device 300. The conductive material may include tungsten, copper, aluminum, alloys of these metals and/or combinations thereof. In one embodiment of the disclosure, the contact structures 330 are preferably formed of tungsten.

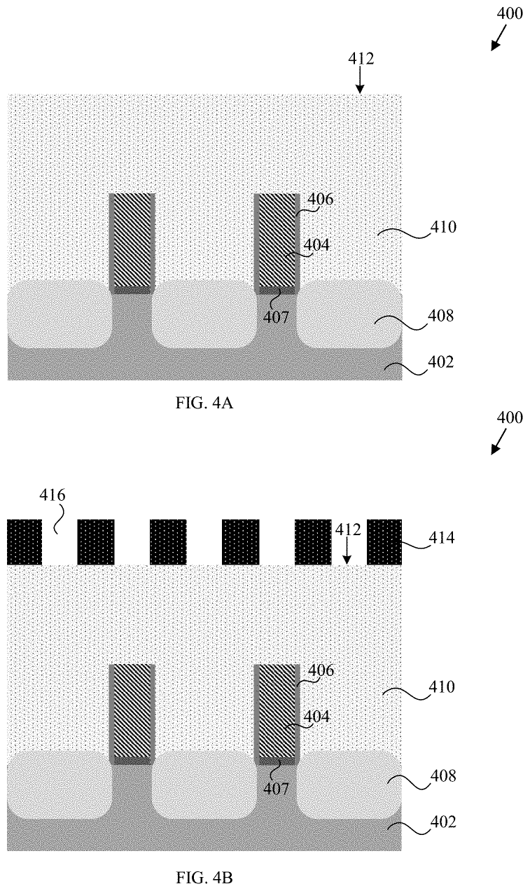

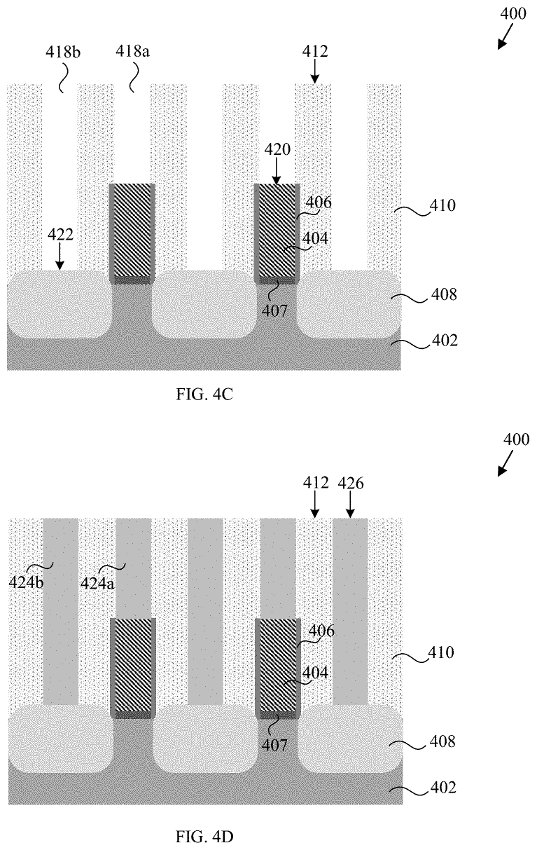

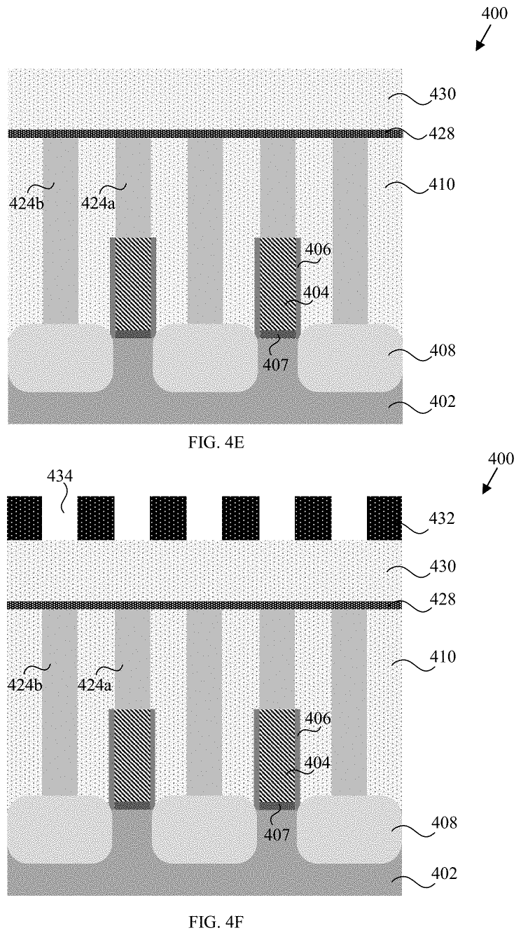

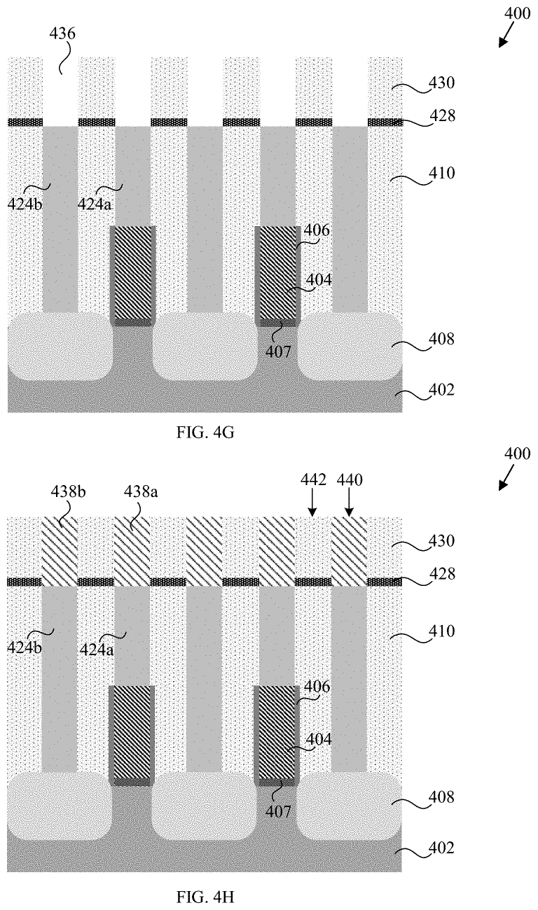

With continuing reference from FIG. 2 and, in particular, the line X-X′ shown therein, FIGS. 4A-4H are enlarged cross-sectional views of a semiconductor device 400 (taken along a similar line X-X′), illustrating an embodiment directed to another method of forming contact structures over an active region of a semiconductor device, according to the present disclosure. It is understood that the specific arrangement of the semiconductor device 400 is used for illustration purposes only and that a variety of possible layouts may benefit from embodiments of the disclosure described herein.

FIG. 4A is a cross-sectional view of the semiconductor device 400, according to an embodiment of the disclosure. Similar to the semiconductor device 300 of FIG. 3A, the semiconductor device 400 includes an active region 402 and gate structures 404. The gate structures 404 are formed over the active region 402 and each of the gate structures 404 having sidewalls disposed with gate spacers 406 and a gate dielectric layer 407. The gate spacers 406 may be formed of a suitable low-k dielectric material, preferably silicon nitride, silicon oxide or any suitable low-k dielectric material to at least contribute to electrically isolate the gate structure 404 from adjacent conductive features. Each of the gate structures 404 is interposed between two epitaxial regions 408. The epitaxial regions 408 are typically formed by an epitaxial growth process or an implantation process and form source/drain regions of the semiconductor device 400.

The gate structure 404 typically includes a layer of gate insulating material, (e.g., a layer of high-k dielectric material having a dielectric constant of typically 10 or greater) or silicon dioxide, and one or more conductive material layers, e.g., metal and/or polysilicon, that serve as gate electrode for the gate structure 404. The gate insulating material and the conductive material layers are not separately shown in the accompanying drawings.

A dielectric layer 410 is deposited over the gate structures 404 and the epitaxial regions 408 using a suitable deposition process. The dielectric layer 410 may be deposited in a one or a multi-step process, and a suitable planarization process may be performed to form a substantially planar top dielectric surface 412. The dielectric layer 410 is preferably a dielectric material, e.g., silicon dioxide, suitable to electrically isolate conductive features ultimately formed therein while maintaining a robust structure during the subsequent processing steps.

FIG. 4B illustrates the semiconductor device 400 after depositing a patterning layer 414 and forming openings 416 in the patterning layer 414, according to an embodiment of the disclosure. The patterning layer 414 is deposited over the dielectric layer 410 and the openings 416 are formed in the patterning layer 414 using suitable deposition and lithographic processes. The openings 416 are aligned over the gate structures 404 and the epitaxial regions 408 and expose portions of the dielectric layer 410. The patterning layer 414 may include a spin-on hard mask (SOH) layer, a photoresist layer, or any suitable patterning layer having any suitable thickness. The patterning layer 414 may also include a multi-layer stack of patterning materials.

FIG. 4C illustrates the semiconductor device 400 after forming interconnect openings 418 in the dielectric layer 410, according to an embodiment of the disclosure. The openings 416 in the patterning layer 414 are extended through the dielectric layer 410 using a suitable material removing process to form the interconnect openings 418 in the dielectric layer 410 over the gate structures 404 and the epitaxial regions 408.

Top surfaces 420 of the gate structures 404 are exposed in the interconnect openings 418a and top surfaces 422 of the epitaxial regions 408 are exposed in the interconnect openings 418b. Although, the interconnect openings 418a over the gate structures 404 and the interconnect openings 418b over the epitaxial regions 408 are illustrated to have the same width in FIG. 4C, different widths of the interconnect openings 418 have been contemplated. In one embodiment of the disclosure, the interconnect openings 418b over the epitaxial regions 408 are preferably wider than the interconnect openings 418a over the gate structures 404, enabling higher current drive through ultimately formed interconnect structures. Additionally, the interconnect openings 418a preferably have the same width as the gate structures 404 as illustrated, however, wider or narrower widths have been contemplated.

It is recognized in this present disclosure that the dielectric layer 410 over the gate structures 404 has a thinner thickness than that over the epitaxial regions 408. As a result, it is possible to predict a shorter period of time it will take to remove the dielectric layer 410 to form the interconnect openings 418a to the gate structures 404 as compared to a longer period of time it will take to remove the dielectric layer 410 to form the interconnect openings 418b to the epitaxial regions 408. The material removing process may include a dry etching process, e.g., a reactive ion etching (ME) process or any suitable material removing process with an etch chemistry having a greater selectivity for the dielectric layer 410 than for the gate structure 404. For instance, an etch chemistry may be selected such that the material removal rate of the dielectric layer 410 is much higher than that of the gate structure 404. Accordingly, the interconnect openings 418b continue to extend to the epitaxial regions 408 while the extension of the interconnect openings 418a at the gate structures 404 will be substantially impeded due to the lower material removal rate of the gate structure material. A portion of the gate structure 404 may or may not be removed by the material removing process during the extension of the interconnect openings 418b to the epitaxial regions 408.

FIG. 4D illustrates the semiconductor device 400 after forming interconnect structures 424, according to an embodiment of the disclosure. The interconnect structures 424 may be formed by any suitable process, including an exemplary process described herein. A conductive material is deposited in the interconnect openings 418 using a suitable deposition process. The conductive material may overfill the interconnect openings 418 and a suitable planarization process may be performed to form a top interconnect surface 426 substantially coplanar with the top surface 412 of the dielectric layer 410. The interconnect structures 424a are electrically connected to the gate structures 404 and the interconnect structures 424b are electrically connected to the epitaxial regions 408, respectively. The interconnect structures 424 have a line-type structure that typically traverses across at least two active regions 402 of the semiconductor device 400, as illustrated in FIG. 2. The conductive material may include tungsten, copper, aluminum, alloys of these metals and/or combinations thereof. In one embodiment of the disclosure, the interconnect structures 426 are preferably formed of tungsten.

Although not shown in FIG. 4D, one or more liners may be deposited in the interconnect openings 418 before the conductive material deposition. For instance, an adhesion liner and/or a barrier liner may be deposited in the interconnect openings 418 before the conductive material deposition. The adhesion liner may include metal silicides, such as titanium silicide, nickel silicide or other suitable adhesion material having any suitable thickness. The barrier liner may include metal nitrides, such as titanium nitride, tantalum nitride or other suitable barrier material having any suitable thickness.

FIG. 4E illustrates the semiconductor device 400 after depositing an etch stop layer 428 and a dielectric layer 430, according to an embodiment of the disclosure. The etch stop layer 428 is deposited over the dielectric layer 410 and the interconnect structures 424, and the dielectric layer 430 is deposited over the etch stop layer 428, using suitable deposition processes. The dielectric layer 430 may or may not be the same dielectric material as the dielectric layer 410. In this embodiment of the disclosure, the dielectric layer 430 and the dielectric layer 410 have the same dielectric material. Also in another embodiment of the disclosure, the etch stop layer 428 is a contact etch stop layer (CESL), and may preferably include a material that exhibits high etch selectivity to the dielectric layer 430. For instance, an employed material removing process may remove the dielectric layer 430 without substantially removing the etch stop layer 428. The etch stop layer 428 may include a silicon carbonitride layer, a silicon nitride layer, a silicon carbide layer or other suitable etch stop layer having any suitable thickness.

FIG. 4F illustrates the semiconductor device 400 after depositing a patterning layer 432 and forming openings 434 in the patterning layer 432, according to an embodiment of the disclosure. The patterning layer 432 is deposited over the dielectric layer 430 and the openings 434 are formed in the patterning layer 432 using suitable deposition and lithographic processes. The openings 434 are aligned over the interconnect structures 424. The patterning layer 432 may include a spin-on hard mask (SOH) layer, a photoresist layer, or any suitable patterning layer having any suitable thickness. The patterning layer 432 may also include a multi-layer stack of patterning materials.

FIG. 4G illustrates the semiconductor device 400 after forming contact openings 436 over the interconnect structures 424, according to an embodiment of the disclosure. The contact openings 436 are formed in the dielectric layer 430 and the etch stop layer 428 using suitable lithographic and material removing processes and the contact openings 436 are positioned over the interconnect structures 424. The contact openings 436 may be in a form of a line-type opening that typically traverses across at least two active regions 402. The material removing process may include one or more dry etching processes, wet etching processes, other suitable etching processes (e.g., reactive ion etching), and/or combinations thereof. The contact openings 436 preferably have the same width as the interconnect structures 424, even though wider or narrower widths have been contemplated.

The contact openings 436 may be formed in a one, a two or a multi-step process. In an embodiment of the disclosure, the contact openings 436 may be formed in the dielectric layer 430 by performing a first material removing process, the contact openings 436 stopping at the etch stop layer 428. A second material removing process may be performed to form the contact openings (not shown) over other portions of the semiconductor device 400, i.e., over shallow trench isolation regions. The second material removing process extends the contact openings 436 through the etch stop layer 428 to the interconnect structures 424. In another embodiment of the disclosure, the contact openings 436 may be formed over the interconnect structures 424 after forming the contact openings (not shown) over other portions of the semiconductor device 400.

The etch stop layer 428 may be selected based upon etch selectivity to one or more features of the semiconductor device 400. For instance, the first material removing process may exhibit a high etch selectivity between the dielectric layer 430 and the etch stop layer 428, such that the first material removing process removes the dielectric layer 430 without substantially removing the etch stop layer 428. The second material removing process may exhibit a high etch selectivity between the etch stop layer 428 and the dielectric layer 430, such that the second material removing process removes the etch stop layer 428 without substantially removing the dielectric layer 430. In this embodiment of the disclosure, the etch stop layer 428 is a contact etch stop layer (CESL) and may include a silicon carbonitride layer, a silicon nitride layer, a silicon carbide layer or other suitable etch stop layer having any suitable thickness.

FIG. 4H illustrates the semiconductor device 400 after forming contact structures 438, according to an embodiment of the disclosure. The contact structures 438 may be formed by an exemplary process described herein. A conductive material is deposited in the contact openings 436. The conductive material may overfill the contact openings 436 and a planarization process may be performed to form a top contact surface 440 substantially coplanar with a top surface 442 of the dielectric layer 430. The contact structures 438a are electrically connected to the gate structures 404 through the interconnect structures 424a and the contact structures 438b are electrically connected to the epitaxial regions 408 through the interconnect structures 424b, respectively.

As illustrated in FIG. 2, the contact structures 438a and 438b may be in a form of a line-type structure that typically traverses across at least two active regions 402 of the semiconductor device 400. The conductive material may include tungsten, copper, aluminum, alloys of these metals and/or combinations thereof. In one embodiment of the disclosure, the contact structures 438 are preferably formed of tungsten.

It is understood that the semiconductor devices 300 and 400 may undergo further semiconductor processing steps to form various features known in the art. For instance, a plurality of conductive vias may be formed to establish an electrical connection between the contact structures and the back-end-of-line (BEOL) regions of the semiconductor devices 300 and 400. The BEOL region typically includes a plurality of conductive lines and interconnect vias that are routed as needed across the semiconductor devices 300 and 400.

In the above detailed description, methods of forming contact structures over an active region of a semiconductor device and the resulting semiconductor devices are presented. The contact structures may be discrete contact structures or line-type contact structures formed over the gate structures in a location where the gate structures traverse across the active regions of the semiconductor device. The placements of these contact structures over an active region enable shorter electrical paths through the gate structures and thus reducing undesirable gate resistance. Reducing gate resistance is advantageous for radio frequency (RF) devices as the performance of the RF devices is sensitive to gate resistance. The disclosed methods of forming contact structures over an active region of a semiconductor device are also particularly advantageous for RF devices. The RF devices are typically fabricated in regions of the semiconductor device having wide gate pitch, e.g., at least 1.5×CPP, and adopting the disclosed methods present a simpler process flow for forming contact structures over an active region of a semiconductor device.

The terms “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the device described herein are, for example, capable of operation in other orientations than those illustrated or otherwise described herein.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

While several exemplary embodiments have been presented in the above detailed description of the device, it should be appreciated that a number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

1. A method of fabricating a semiconductor device comprising:
providing a plurality of fins over a substrate;
forming a plurality of first gate structures having a first gate pitch traversing across a first set of fins;
forming a plurality of second gate structures having a second gate pitch traversing across a second set of fins, wherein the second gate pitch is wider than the first gate pitch;
forming a plurality of epitaxial regions in spaces between adjacent second gate structures in each of the traversed second set of fins;
forming a dielectric layer having a first dielectric portion and a second dielectric portion over the plurality of second gate structures and the plurality of epitaxial regions, wherein an etch stop layer is interposed between the first and second dielectric portions;
forming a plurality of contact openings in the dielectric layer, wherein at least one of the contact openings is formed over the second gate structure at a location where the second gate structure traverses across the second set of fins; and
filling the plurality of contact openings with a conductive material to form a plurality of contact structures electrically coupled to the second gate structures.

2. The method of claim 1, wherein the plurality of contact openings are a plurality of first contact openings and the plurality of contact structures are a plurality of first contact structures, further comprises:
forming a plurality of second contact opening s in the second dielectric portion, wherein the plurality of second contact openings traverse across the second set of fins in the spaces between the adjacent second gate structures on the plurality of epitaxial regions formed in each of the second set of fins; and
filling the plurality of second contact openings, concurrently with the filling of the plurality of first contact openings, with the conductive material to form a plurality of second contact structures electrically coupled to the epitaxial regions.

3. The method of claim 2 further comprises:
forming a plurality of interconnect structures in between and electrically connecting the plurality of epitaxial regions to the second contact structures in the first dielectric portion.

4. The method of claim 1 wherein forming the plurality of contact openings, further comprises etching the dielectric layer to form discrete contact openings.

5. The method of claim 2 wherein forming of the plurality of second contact openings further comprises etching the dielectric layer to form line-type contact openings that traverse across the second set fins.

6. The method of claim 1, wherein the plurality of contact openings are a plurality of first contact openings and the plurality of contact structures are a plurality of first contact structures, further comprises:
forming a plurality of second contact openings in the second dielectric portion concurrently with the forming of the plurality of first contact openings, and positioning each of the second contact openings at a location where the second contact openings traverse across the second set of fins in the spaces between the adjacent second gate structures over the plurality of epitaxial regions in the second set of fins; and
filling the plurality of second contact openings, concurrently with the filling of the plurality of first contact openings, with the conductive material to form a plurality of second contact structures electrically coupled to the epitaxial regions.

7. The method of claim 6 further comprises:
forming concurrently a plurality of first interconnect structures over the plurality of second gate structures and a plurality of second interconnect structures over the plurality of epitaxial regions, wherein each of the first interconnect structures is positioned between and electrically connects the second gate structure to the first contact structure, and wherein each of the second interconnect structures is positioned between and electrically connects the epitaxial region to the second contact structure.

8. The method of claim 6 wherein forming of the plurality of first contact openings and the plurality of second contact openings, further comprises etching the second dielectric portion to form line-type contact openings.

9. The method of claim 1 further comprises forming the plurality of first gate structures having the first gate pitch set as a minimum gate pitch of the semiconductor device.

10-13. (canceled)

14. A semiconductor device comprising:
a plurality of fins over a substrate;
a plurality of gate structures traversing the plurality of fins;
a plurality of epitaxial regions in the plurality of fins;
the epitaxial regions being interposed between adjacent gate structures; and
a first contact structure over each of the gate structures at a location where the gate structure traversing across the plurality of fins, wherein the first contact structure is in a dielectric layer having an interposed etch stop layer.

15. The semiconductor device of claim 14 wherein the first contact structure is a discrete contact structure that is coupled to at least one of the plurality of fins.

16. The semiconductor device of claim 14 wherein the first contact structure is a line-type contact structure that is coupled to at least two of the plurality of fins.

17. The semiconductor device of claim 14 further comprises:
a plurality of interconnect structures that are each positioned between and electrically connecting the plurality of gate structures to the first contact structures.

18. The semiconductor device of claim 14 further comprises:
a second contact structure over each of the epitaxial regions;
a plurality of first interconnect structures over the plurality of gate structures electrically connecting the gate structures and the second contact structure; and
a plurality of second interconnect structure over the plurality of epitaxial regions electrically connecting the second contact structures and the epitaxial regions.

19. The semiconductor device of claim 14, wherein the first contact structure comprises tungsten.

20. (canceled)

21. A semiconductor device comprising:
a fin over a substrate;
a dielectric layer having a first dielectric portion and a second dielectric portion;
an etch stop layer interposed between the first and second dielectric portions;
a gate structure traversing the fin;
an epitaxial region in the fin, the epitaxial region being adjacent to the gate structure;
a first contact structure over the gate structure at a location where the gate structure traverses the fin;
a second contact structure over the epitaxial region, wherein the first and second contact structures are in the dielectric layer.

22. The semiconductor device of claim 21, wherein the first contact structure is in the first and second dielectric portions and extends through the etch stop layer to a top surface of the gate structure.

23. The semiconductor device of claim 21, wherein a bottom portion of the first contact structure is adjacent to the etch stop layer.

24. The semiconductor device of claim 23, further comprising an interconnect structure in the first dielectric portion electrically connecting the first contact to the gate structure.

25. The semiconductor device of claim 21, wherein the first and second contact structures are in the second dielectric portion and having bottom portions adjacent to the etch stop layer.
